(19) United States
(12) Patent Application Publication
(10) Pub. No.: US 2017/0317264 A1
(43) Pub. Date: Nov. 2, 2017

(54) ULTRASONIC TRANSDUCER AND METHOD FOR MANUFACTURING THE SAME

(71) Applicant: CANON KABUSHIKI KAISHA, Tokyo (JP)

(72) Inventor: Toshio Tomiyoshi, Yokohama-shi (JP)

(21) Appl. No.: 15/581,169

(22) Filed: Apr. 28, 2017

(30) Foreign Application Priority Data
Apr. 29, 2016 (JP) 2016-092138

(51) Int. Cl. H01L 41/08; H01L 41/23; B06B 1/10; H01L 41/27; B06B 1/06

(52) U.S. Cl. CPC H01L 41/0825; H01L 41/27; B06B 1/06; B06B 1/10; H01L 41/23

(57) ABSTRACT

In an ultrasonic transducer manufacturing method, an ultrasonic device is mounted on a substrate, and a protective film having an acoustic matching layer thereon is prepared. Then, the protective film having the acoustic matching layer thereon is placed over the ultrasonic device such that the acoustic matching layer is in contact with the ultrasonic device.

### BACKGROUND OF THE INVENTION

### Field of the Invention

The present invention relates to an ultrasonic transducer that performs at least one of transmission and reception of ultrasonic waves, and to a method for manufacturing the ultrasonic transducer.

### Description of the Related Art

There are converters called ultrasonic transducers that are capable of performing a conversion between an electrical signal and an ultrasonic signal. The ultrasonic transducers are applied to flaw detection, exploration, and communication techniques, and are used in a wide range of applications in industrial and medical fields. Examples of ultrasonic devices used in the ultrasonic transducers include piezoelectric devices using piezoelectric elements, and capacitive devices including electrodes above and below a cavity. Such ultrasonic devices are connected to wires and electrical circuits to form an ultrasonic transducer which is designed to control the electrical insulation, the efficiency of transmission or reception of ultrasonic waves, and the direction of ultrasonic waves. Mounting such an ultrasonic transducer in a case or housing produces an ultrasonic module.

Ultrasonic devices can be used as an ultrasonic image sensor device by two-dimensionally arranging them. By surface-mounting a plurality of devices on a flexible substrate, the devices can be spatially arranged. This can improve orientation control of ultrasonic waves and spatial resolution. Mounting in a long and narrow area, such as that in an ultrasonic probe, requires not only flexibility, but also high airtightness and electrical insulation properties. Japanese Patent Laid-Open No. 2008-110060 discloses an ultrasonic transducer including a plurality of ultrasonic vibrators. Japanese Patent Laid-Open No. 2009-247511 discloses an ultrasonic imaging apparatus in which a plurality of transducers that transmit and receive ultrasonic waves are arranged on a film.

In the technical fields described above, an ultrasonic transducer typically includes an ultrasonic device mounted on a substrate having electrical wires thereon, and further includes, on the ultrasonic transmission/reception side thereof, an acoustic matching layer for improving ultrasonic conversion efficiency, an acoustic lens for controlling the orientation of ultrasonic waves, and a protective film for preventing external damage and maintaining electrical insulation properties and airtightness. Japanese Patent Laid-Open No. 2008-110060 discloses a technique in which a protective film covers the ultrasonic vibrators to maintain the electrical insulation properties. Japanese Patent Laid-Open No. 2009-247511 discloses a technique in which, after acoustic matching layers are formed on respective lead zirconate titanate (PZT) elements each serving as a transducer that transmits and receives an ultrasonic signal, an acoustic lens is formed over the acoustic matching layers.

Forming the individual acoustic matching layers on the respective ultrasonic devices, as in the technique disclosed in Japanese Patent Laid-Open No. 2009-247511, causes significant variation in positional accuracy and bonding strength. The variation is reduced very little even by placing a protective member of uniform thickness over the acoustic matching layers. When a large number of very small devices are mounted on a considerably uneven surface to form a transducer, it is difficult to reduce the thickness of the acoustic matching layers on the transmission/reception side and its variation.

### SUMMARY OF THE INVENTION

In view of the problems described above, an aspect of the present invention provides an ultrasonic transducer manufacturing method for manufacturing an ultrasonic transducer including an ultrasonic device configured to perform at least one of transmission and reception of ultrasonic waves. The ultrasonic transducer manufacturing method includes mounting the ultrasonic device on a substrate; preparing a protective film having an acoustic matching layer thereon; and placing the protective film having the acoustic matching layer thereon over the ultrasonic device such that the acoustic matching layer is in contact with the ultrasonic device.

In view of the problems described above, another aspect of the present invention provides an ultrasonic transducer including a substrate; an ultrasonic device disposed on the substrate, the ultrasonic device being configured to perform at least one of transmission and reception of ultrasonic waves; and a continuous protective film having an acoustic matching layer thereon, the protective film being disposed over the ultrasonic device and the substrate to cover the ultrasonic device and the substrate together such that the acoustic matching layer is in contact with the ultrasonic device.

In the aspects of the present invention described above, the protective film having the acoustic matching layer on one side thereof is placed such that the acoustic matching layer tightly adheres to, or is in contact with, the ultrasonic device. More specifically, the continuous protective film having the acoustic matching layer thereon is placed to cover the ultrasonic device and the substrate (including wires, where applicable) together. This not only reduces air bubbles which may degrade ultrasonic sensitivity on the transmission/reception surface of the ultrasonic device, but also secures a large bonding area and thereby improves the bonding strength.

Further features of the present invention will become apparent from the following description of exemplary embodiments with reference to the attached drawings.

### BRIEF DESCRIPTION OF THE DRAWINGS

FIGS. 1A-1, 1A-2, 1B-1, 1B-2, 1C-1, and 1C-2 illustrate an ultrasonic transducer manufacturing method according to a first embodiment of the present invention.

FIGS. 2A to 2D illustrate an ultrasonic transducer manufacturing method according to a second embodiment of the present invention.

FIGS. 3A to 3D illustrate an ultrasonic transducer manufacturing method according to a third embodiment of the present invention.

FIGS. 4A to 4D illustrate an ultrasonic transducer manufacturing method according to a fourth embodiment of the present invention.

### DESCRIPTION OF THE EMBODIMENTS

Embodiments of an ultrasonic transducer according to the present invention will be described with reference to the drawings. Note that configurations and materials described below are merely examples, and can be appropriately changed as long as advantageous effects of the present invention can be achieved.

### First Embodiment

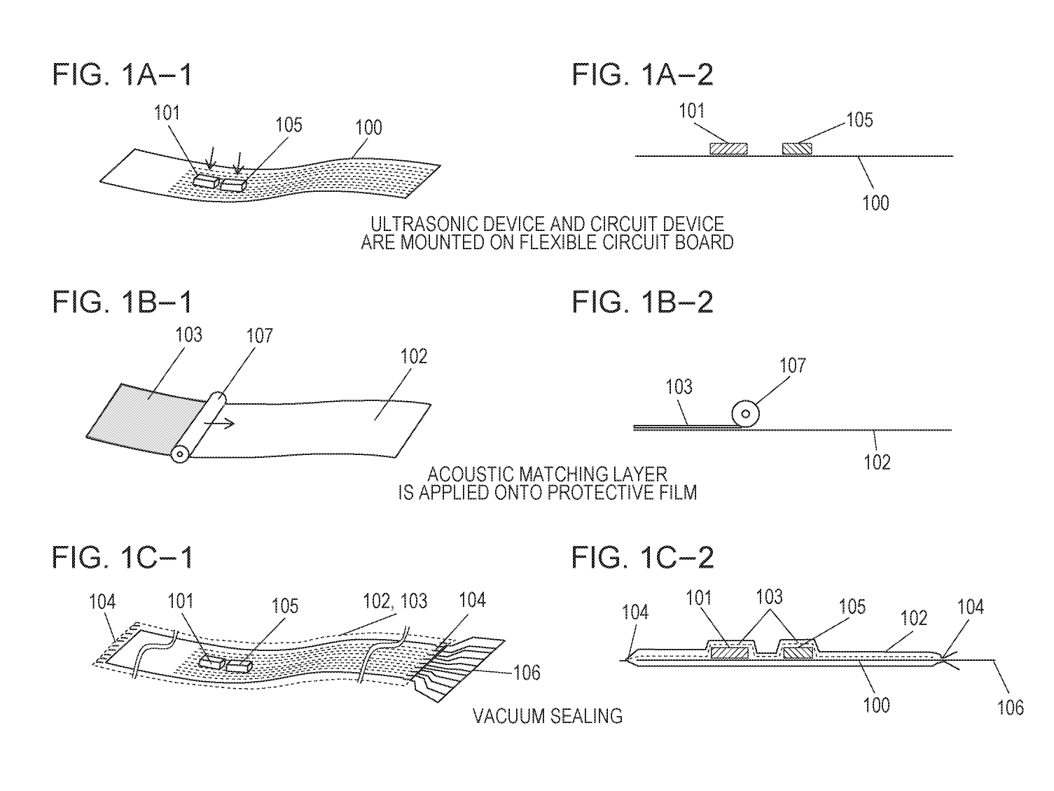

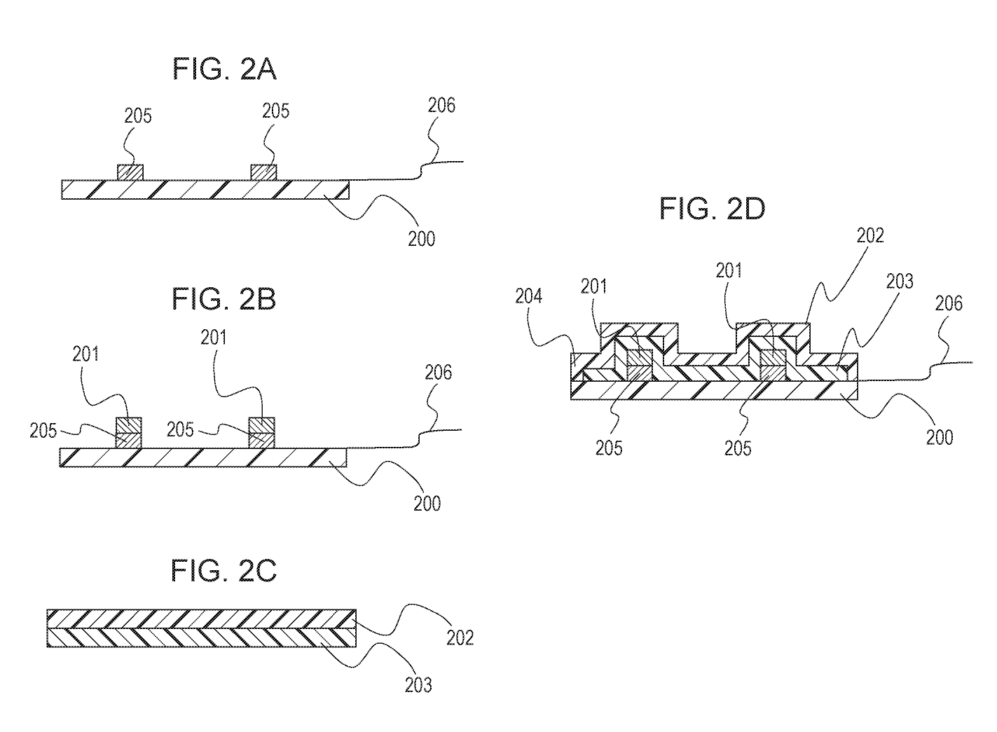

A configuration of an ultrasonic transducer and a method for manufacturing the ultrasonic transducer according to a first embodiment of the present invention will be described. FIGS. 1A-1, 1B-1, and 1C-1 are perspective views illustrating an ultrasonic transducer manufacturing method according to the present embodiment. FIGS. 1A-2, 1B-2, and 1C-2 are cross-sectional views of FIGS. 1A-1, 1B-1, and 1C-1. In the drawings, reference numeral 100 denotes a substrate having flexibility, reference numeral 101 denotes a transmitting and/or receiving ultrasonic device, reference numeral 102 denotes a protective film, and reference numeral 103 denotes an acoustic matching layer. Reference numeral 104 denotes a sealed portion of the protective film 102, reference numeral 105 denotes a circuit device (e.g., IC device or electrical circuit device, such as a resistor or capacitor), and reference numeral 106 denotes an electrode extended portion where electrodes are extended to the outside. Silicone resin or the like used to form the acoustic matching layer 103 may be used as an adhesive material to form all or part of the sealed portion 104. The sealed portion 104 may be formed by applying pressure or thermocompression bonding to the protective film 102. The silicone resin may be of any type as long as it is flexible, causes less attenuation of ultrasonic waves in the acoustic matching layer 103, and allows the acoustic matching layer 103 to be formed in a uniform thickness.

In the present embodiment, a flexible circuit board (flexible printed circuit board) is used as the substrate 100 (hereinafter referred to as “flexible circuit board 100”). Wires on the flexible circuit board 100 may be exposed to the outside only at connection terminal portions thereof, or may be exposed entirely including the connection terminal portions thereof. When exposed, the wires and the connection terminal portions thereof, except the electrode extended portion 106, are insulated by being sealed with the protective film 102. Alternatively, the protective film 102 may be formed on the flexible circuit board 100 to ensure insulation properties. The flexible circuit board 100 is a flexible substrate manufactured by forming a pattern of gold or the like on a highly flexible film made of polyimide-based material or the like. In the present manufacturing method, first, the ultrasonic device 101 in a chip form is mounted on the flexible circuit board 100 and electrically connected thereto by soldering, wire bonding, or a metal bonding technique. The ultrasonic device 101 may be secured to the flexible circuit board 100 by any technique as long as the ultrasonic device 101 can be secured in place. For example, the ultrasonic device 101 may be secured by using a metal bonding technique, an adhesive, or a double-faced tape. Similarly, the circuit device 105 is secured in place and electrically connected to the flexible circuit board 100 (see FIGS. 1A-1 and 1A-2).

In a separate process, the acoustic matching layer 103 is uniformly applied to one side of the protective film 102 using a roll coater 107 (see FIGS. 1B-1 and 1B-2). The protective film 102 has a thickness of 50 μm or less and is made of polyethylene terephthalate (PET) resin with high flexibility, insulation properties, and humidity resistance. The protective film 102 may be a highly flexible thin film made of polyethylene resin, polypropylene resin, polyimide resin, polyvinyl resin, silicone resin, or other materials having high moisture resistance and environmental resistance comparable to the above-described resins and not degrading ultrasonic signals. The acoustic matching layer 103 has a thickness of 50 μm or less, and is made of resin (such as silicone resin) capable of adjusting acoustic impedance and having high flexibility and insulation properties. The protective film 102 coated with the acoustic matching layer 103 is bonded to a side of the flexible circuit board 100 having the ultrasonic device 101 and the circuit device 105 mounted thereon as in FIGS. 1A-1 and 1A-2 such that the acoustic matching layer 103 is in contact with the ultrasonic device 101. The protective film 102 is also placed over the other side of the flexible circuit board 100, which is thus vertically sandwiched and then sealed by lamination in a vacuum (see FIGS. 1C-1 and 1C-2).

The flexible circuit board 100 is covered, except part of the electrode extended portion 106, by the protective film 102 coated with the acoustic matching layer 103. It is desirable that the protective film 102 be slightly wider than the flexible circuit board 100. Vacuum lamination is a sealing technique which involves lowering the pressure between a sealed member and a sealing member to remove gas containing air as much as possible. The sealing process involves putting the entire system into a vacuum, bonding a sealed member and a sealing member together with no gas therebetween, and taking out the entire system under atmospheric pressure. The sealing process may involve covering a sealed member with a bag-like sealing member, and removing gas inside the sealing member. Vacuum lamination is a vacuum sealing technique which includes the processes described above. The protective film 102 has a smooth and even surface before sealing, and this allows the acoustic matching layer 103 to be applied to the protective film 102 in a uniform thickness. For better adhesion between the protective film 102 and the acoustic matching layer 103, the protective film 102 may be subjected to pretreatment, such as plasma treatment or primer treatment.

The protective film 102 may be in the shape of a sleeve or bag. In this case, the protective film 102 is formed after the acoustic matching layer 103 is formed using a mold or the like. The flexible circuit board 100 is inserted into the protective film 102 in a sleeve or bag shape and the sealed portion 104 is formed in the electrode extended portion 106. It is desirable to minimize the area of the sealed portion 104. Even when the protective film 102 is in the shape of a sleeve or bag, the same advantageous effects as those with vacuum lamination can be achieved by sealing in a vacuum. In parallel with the ultrasonic device 101, the circuit device 105 (such as a current-voltage conversion circuit or a signal amplification circuit) is mounted on the flexible circuit board 100, and the protective film 102 is formed at the same time. This enables protection from the outside and improves device characteristics.

In the manufacturing method according to the present embodiment, the protective film 102 is uniformly coated with the acoustic matching layer 103 in advance, and then the entire flexible circuit board 100 is sealed in a vacuum with the protective film 102 having the acoustic matching layer 103 thereon. Ultrasonic transducers with less variation in characteristics among ultrasonic devices can thus be produced. Since a plurality of ultrasonic devices and their periphery circuits are protected together with circuit devices, the negative impact of many seams and sealed portions can be avoided and the yield of ultrasonic transducers can be increased.

The ultrasonic transducer manufacturing method according to the present embodiment is suitable for manufacturing an ultrasonic transducer in which a flexible circuit board is used as a substrate. This is because ultrasonic devices are not dependent on the type or shape (such as one- or two-dimensional array), and can be freely changed in shape or form by coupling them using electrical wires. Even when an ultrasonic transducer is bent or deformed by external force, or is used in a bent state on a flexible probe or the like, local stress concentration and damage can be avoided, because both the substrate and the protective film are made of flexible materials. This means that the ultrasonic transducer is resistant to performance degradation and highly reliable over a long period of time.

Vacuum sealing does not require high temperature on the devices or over the entire substrate. It is thus desirable that the protective film used for lamination be made of material with low permeability to gas and water, such as polyethylene terephthalate (PET) or polypropylene (PP). To follow the contour of the substrate, the protective film is preferably made of highly flexible material with a Young's modulus of 3 GPa to 30 GPa. To achieve both protection and flexibility and reduce attenuation of ultrasonic waves, the protective film is preferably about 5 μm to 40 μm in thickness.

Typical examples of the ultrasonic transducer include piezoelectric and capacitive devices. Since the piezoelectric and capacitive devices are often driven at a high voltage, they require a protective film which entirely covers them for safety purposes. The protective film needs to be free from electrical leakage, highly airtight, and resistant to damage and peeling by stress. The material used to form the protective film and the sealing performed with the protective film need to be resistant to degradation over a long period of time. High-density mounting of ultrasonic devices may increase the number of wires and cause signal degradation. The ultrasonic transducer manufacturing method according to the present embodiment is preferable in that it is possible not only to increase the degree of freedom in complex mounting of an ultrasonic device and its amplification circuit and in wiring for connection to the mounted components, but also to obtain stable ultrasonic signals.

The protective film of the ultrasonic transducer will be further described. As described above, a film with high electrical insulation properties, humidity resistance, and flexibility is used as the protective film. To improve ultrasonic propagation characteristics of the ultrasonic transducer, it is preferable to use the protective film coated with an acoustic matching layer which also serves as an adhesive layer. It is preferable that the acoustic matching layer be formed in a uniform thickness of 300 μm or less. For better adhesion between the acoustic matching layer and the protective film, it is preferable that the protective film be subjected to pretreatment, such as plasma treatment, ozone treatment, or primer treatment.

In the manufacturing method described above, a first sealing film is prepared by forming, on a protective film with a uniform thickness, an acoustic matching layer in a uniform thickness. Next, a flexible circuit board is prepared by forming wires, containing gold, on a base made primarily of polyimide with high flexibility. Ultrasonic devices are mounted on the flexible circuit board. The ultrasonic devices are electrically connected to the flexible circuit board using, for example, wire bonding or through-vias. Similarly, IC devices and circuit chips may also be mounted on the flexible circuit board and electrically connected thereto.

Like the first sealing film, a second sealing film is prepared by forming, on a protective film with a uniform thickness, an acoustic matching layer in a uniform thickness. The first and second (or upper and lower) sealing films do not necessarily need to be the same ones. The second sealing film may be formed only by the protective film. The protective film may be of any type, as long as it is thin and flexible and can provide characteristics equivalent to those achieved with polyethylene terephthalate (PET) which is chemically stable.

The material and thickness of the acoustic matching layer on the ultrasonic transmission/reception side are determined by taking into account the acoustic matching of the ultrasonic device, an object to be measured, and the protective film. A sealing film on the other side may be of any type that can maintain adhesion and sealing properties. That is, the two sealing films may be of different resins and thicknesses. The first and second sealing films are placed in order, with the flexible circuit board having the ultrasonic devices thereon sandwiched therebetween, and the flexible circuit board is sealed by vacuum lamination. As described above, one sealing film on the ultrasonic transmission/reception side is a film of a configuration and material suitable for acoustic matching, and the other sealing film is designed to serve as a sealing support film. If ultrasonic devices are mounted on both sides, that is, if the flexible circuit board has ultrasonic transmission/reception surfaces on both sides, it is preferable to use a protective film coated with an acoustic matching layer for both sides, and simultaneously perform sealing in a vacuum. A seamless protective film (sealing film) with no seams between devices is thus formed over a plurality of devices and circuit chips mounted on the flexible circuit board.

The ultrasonic transducer manufacturing method may further include a step of forming a light reflecting layer on the protective film. The light reflecting layer may be made of gold. There may be a step of forming an adhesive layer on the protective film, and forming a light reflecting layer on the adhesive layer. The adhesive layer may be a polydimethylsiloxane (PDMS) layer. The light reflecting layer is designed for use in a photoacoustic tomography (PAT) system. The PAT system is configured to apply light from an LED or laser to an object to be measured, and receive an acoustic wave returned therefrom. To prevent noise caused by stray light entering ultrasonic elements, a material primarily of gold (Au) having high infrared reflectance is formed into a light reflecting layer.

In the present embodiment, a uniform protective film having an acoustic matching layer thereon (i.e., sealing film) can be formed by applying an acoustic matching layer to a protective film in advance. By covering, with this sealing film, a flexible circuit board and a plurality of ultrasonic devices and IC devices mounted thereon, a soft and seamless structure with no seams between devices can be provided. By using vacuum lamination, a high level of adhesion between each device and the acoustic matching layer or protective film can be achieved. Also, entry of air bubbles, which may significantly attenuate ultrasonic propagation characteristics, can be prevented. By using vacuum lamination for bonding the substrate and the protective film manufactured as described above, the level of adhesion and uniformity can be improved. When the protective film having the acoustic matching layer thereon tightly adheres to each device and the flexible circuit board, a shape that follows the curved contour of the devices can be provided. It is thus possible to provide a highly flexible ultrasonic transducer which is free from stress on gaps between devices and has durability to withstand bending. An ultrasonic transducer manufacturing method can thus be provided, in which when a component is placed over a plurality of ultrasonic devices, entry of air bubbles can be reduced and a sufficient bonding area can be secured. It is also possible to reduce variation among ultrasonic devices in the ultrasonic transducer. The ultrasonic transducer manufactured as described above can provide an ultrasonic module having a high degree of freedom, in accordance with the intended application, such as a curved housing or a long and narrow probe.

The acoustic matching layer formed on one side of the protective film in advance has less variation in thickness, and sealing is carried out using vacuum lamination. It is thus possible to provide an ultrasonic transducer which can reduce entry of air bubbles and has high ultrasonic propagation efficiency. Since a protective film formed by vacuum lamination has high adhesion, it is possible to provide an ultrasonic transducer which is free from the risk of electrical leakage even in wet locations and is highly reliable over a long period of time. When IC devices or electrical circuit devices are mounted near ultrasonic devices on the same substrate, it is possible to reduce the number of wires from the ultrasonic devices, and to provide signal lines which are resistant to crosstalk and noise and have less signal degradation. The ultrasonic devices and the IC devices or electrical circuit devices are pressed against the flexible circuit board under atmospheric pressure by vacuum-laminating them with the protective film. Since this causes the individual devices to tightly adhere to the flexible circuit board, a highly reliable ultrasonic transducer can be provided, which is resistant to peeling and free from electrical leakage to the outside. Using the vacuum lamination causes the protective film to be continuously pressed by atmospheric pressure. This makes it possible to ensure contact between the devices and the flexible circuit board.

### Second Embodiment

An ultrasonic transducer manufacturing method according to a second embodiment of the present invention will be described. FIGS. 2A to 2D are schematic cross-sectional views of an ultrasonic transducer according to the present embodiment. The present embodiment deals with a method for manufacturing an ultrasonic transducer in which a circuit device is disposed between a substrate and an ultrasonic device. The following mainly describes differences from the first embodiment, and the description of common elements will be omitted or simplified.

In FIGS. 2A to 2D, reference numeral 200 denotes a flexible circuit board having flexibility, reference numeral 201 denotes a transmitting and/or receiving ultrasonic device, reference numeral 202 denotes a protective film, reference numeral 203 denotes an acoustic matching layer, reference numeral 204 denotes a sealed portion of the protective film 202, reference numeral 205 denotes a circuit device (e.g., IC device or electrical circuit device, such as a resistor or capacitor), and reference numeral 206 denotes an electrode extended portion where electrodes are extended to the outside. As in the first embodiment described above, the flexible circuit board 200 is manufactured by forming conductive wires made of gold or the like on a highly flexible film. The circuit devices 205 are mounted on the flexible circuit board 200 (see FIG. 2A). Then, the ultrasonic devices 201 are mounted on the respective circuit devices 205 (see FIG. 2B). The circuit devices 205 are mainly formed by signal amplification circuits, and are connected to the ultrasonic devices 201 by, for example, metal bonding using through-vias. An electrical connection between the flexible circuit board 200 and each of the circuit devices 205 is made by soldering, wire bonding, or metal bonding. The circuit devices 205 and the ultrasonic devices 201 may be mounted in reverse order on the flexible circuit board 200.

In a separate process, the acoustic matching layer 203 is applied onto the protective film 202 (see FIG. 2C). The flexible circuit board 200 having the circuit devices 205 and the ultrasonic devices 201 mounted thereon is sealed by vacuum lamination, as in the first embodiment, with the protective film 202 coated with the acoustic matching layer 203 (see FIG. 2D). By positioning each ultrasonic device 201 adjacent to the corresponding circuit device 205 including a signal amplification circuit and a switching circuit therein, it is possible to reduce noise and signal degradation. Although two ultrasonic devices 201 and two circuit devices 205 are mounted on the flexible circuit board 200 in the process illustrated in FIGS. 2A to 2D, the number may be three or more. The same advantageous effects as those in the first embodiment can be achieved in the present embodiment.

### Third Embodiment

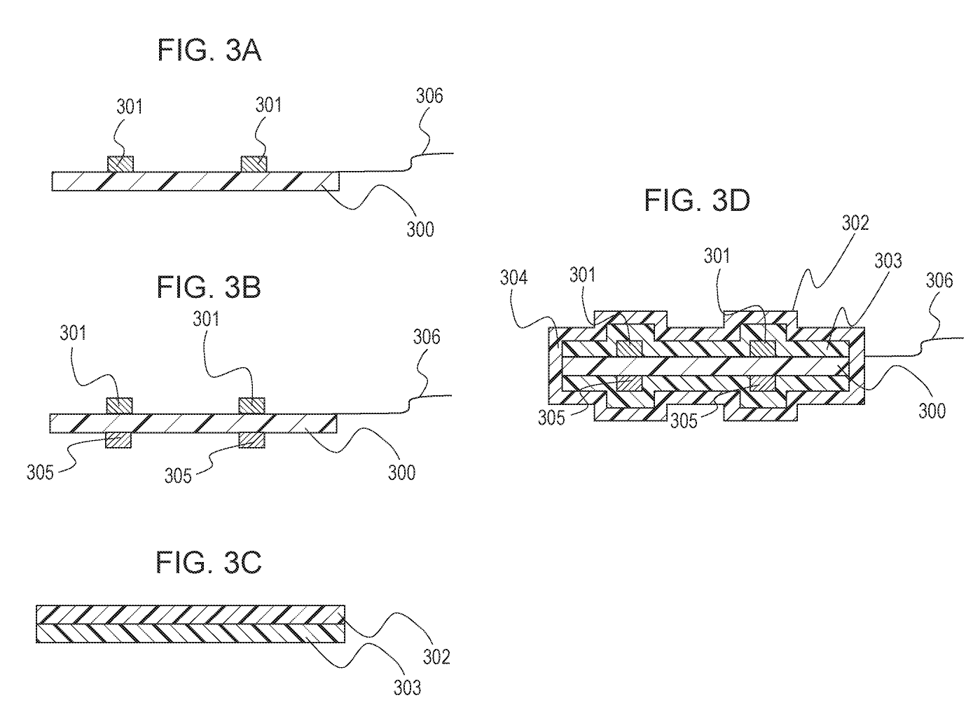

An ultrasonic transducer manufacturing method according to a third embodiment of the present invention will be described. FIGS. 3A to 3D are schematic cross-sectional views of an ultrasonic transducer according to the present embodiment. The present embodiment deals with an ultrasonic transducer in which the substrate has ultrasonic devices on one of two principal surfaces thereof and circuit devices on the other principal surface (back surface) thereof. The following mainly describes differences from the first embodiment, and the description of common elements will be omitted or simplified.

In FIGS. 3A to 3D, reference numeral 300 denotes a flexible circuit board having flexibility, reference numeral 301 denotes a transmitting and/or receiving ultrasonic device, reference numeral 302 denotes a protective film, reference numeral 303 denotes an acoustic matching layer, and reference numeral 304 denotes a sealed portion of the protective film 302. Reference numeral 305 denotes a circuit device (e.g., IC device or electrical circuit device, such as a resistor or capacitor), and reference numeral 306 denotes an electrode extended portion where electrodes are extended to the outside.

The flexible circuit board 300 is manufactured by forming conductive wires made of gold or the like on a highly flexible film. The ultrasonic devices 301 are mounted on one surface of the flexible circuit board 300 (see FIG. 3A), and then the circuit devices 305 are mounted on the other surface of the flexible circuit board 300 (see FIG. 3B). The ultrasonic devices 301 and the circuit devices 305 are individually electrically connected to the flexible circuit board 300 by soldering, wire bonding, or metal bonding. The mounting can be done in any order. The ultrasonic devices 301 may be connected on the back sides thereof to the respective circuit devices 305, with the flexible circuit board 300 interposed therebetween. When each ultrasonic device 301 and the corresponding circuit device 305 are positioned at substantially the same location on both sides of the flexible circuit board 300, the flexibility of the flexible circuit board 300 is not significantly lost.

In a separate process, the acoustic matching layer 303 is applied onto the protective film 302 (see FIG. 3C). The flexible circuit board 300 having the ultrasonic devices 301 and the circuit devices 305 mounted thereon is sealed on both principal surfaces thereof by vacuum lamination, as in the first embodiment, with the protective film 302 coated with the acoustic matching layer 303 (see FIG. 3D). By positioning each ultrasonic device 301 adjacent to the corresponding circuit device 305 including a signal amplification circuit and a switching circuit therein, it is possible to reduce signal degradation and prevent noise contamination. The same advantageous effects as those in the first and second embodiments can be achieved in the present embodiment.

### Fourth Embodiment

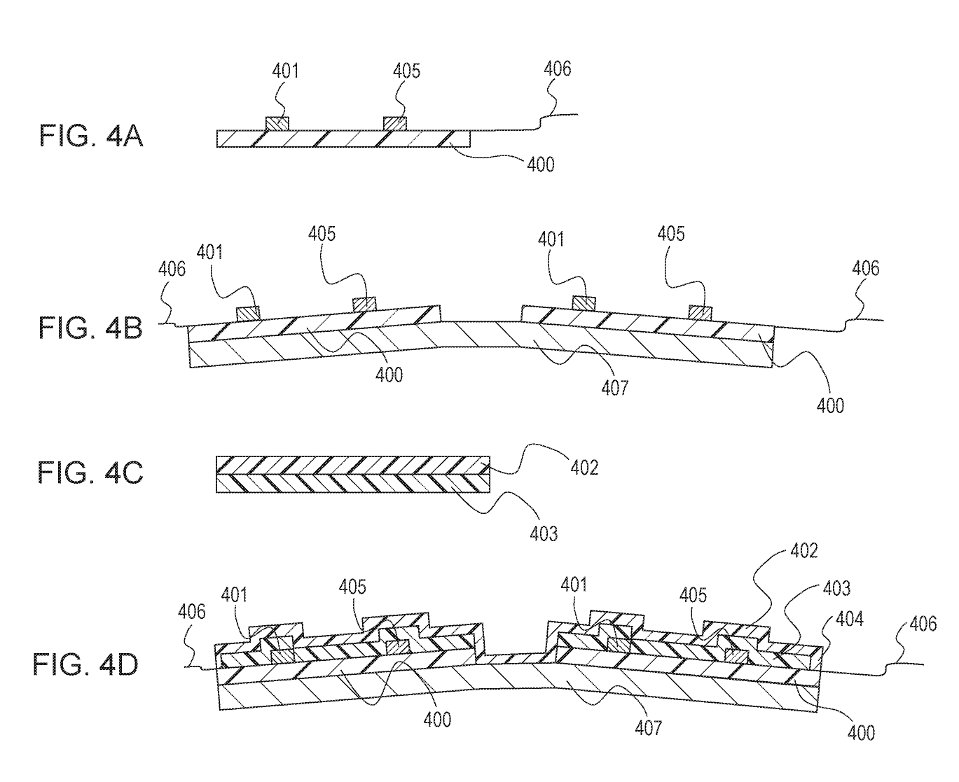

An ultrasonic transducer manufacturing method according to a fourth embodiment of the present invention will be described. FIGS. 4A to 4D are schematic cross-sectional views of an ultrasonic transducer according to the present embodiment. The following mainly describes differences from the first embodiment, and the description of common elements will be omitted or simplified. In FIGS. 4A to 4D, reference numeral 400 denotes a circuit board made of glass epoxy resin or the like and having a typical hardness, reference numeral 401 denotes a transmitting and/or receiving ultrasonic device, reference numeral 402 denotes a protective film, and reference numeral 403 denotes an acoustic matching layer. Reference numeral 404 denotes a sealed portion of the protective film 402, reference numeral 405 denotes a circuit device (e.g., IC device or electrical circuit device, such as a resistor or capacitor), reference numeral 406 denotes an electrode extended portion where electrodes are extended to the outside, and reference numeral 407 denotes a flexible circuit board.

The ultrasonic device 401 and, where necessary, the circuit device 405 are bonded onto the circuit board 400 (see FIG. 4A) and electrically connected thereto by soldering, wire bonding, or the like. A plurality of circuit boards 400 each having the devices mounted thereon are connected by the flexible circuit board 407. One or more circuit boards 400 are thus mounted on the flexible circuit board 407 having high flexibility, and this makes the entire ultrasonic transducer freely bendable (see FIG. 4B). In a separate process, the acoustic matching layer 403 is uniformly applied onto the protective film 402 (see FIG. 4C). The circuit boards 400, each having the devices mounted thereon, and the flexible circuit board 407 connecting the circuit boards 400 are sealed by vacuum lamination, as in the first embodiment, with the protective film 402 coated with the acoustic matching layer 403 and continuously covering the circuit boards 400 and the flexible circuit board 407 together (see FIG. 4D).

Since the circuit boards 400 are hard and highly heat-resistant, a reflow oven may be used in mounting the ultrasonic device 401 and the circuit device 405 on each of the circuit boards 400. Since the circuit boards 400 allow complex wiring thereon, electrical and electronic circuit devices of various shapes can be mounted on the circuit boards 400. The circuit boards 400 can be one- or two-dimensionally connected by the flexible circuit board 407. This gives a high degree of freedom in determining the shape of the ultrasonic transducer. Even when more than two circuit boards 400 are connected, they can be covered together by the continuous protective film 402. It is thus possible to achieve seamless electrical insulation protection and improve durability without sacrificing the flexibility of the ultrasonic transducer. The ultrasonic transducer can bring out uniform performance of its component elements. That is, variation among the component elements of the ultrasonic transducer can be reduced.

In the embodiments of the present invention, when a component, such as a protective film, is placed over an ultrasonic device, entry of air bubbles can be reduced and a sufficient bonding area can be secured. When the protective film is placed over a plurality of ultrasonic devices, variation in ultrasonic vibration characteristics among the ultrasonic devices can be reduced because the acoustic matching layer over the ultrasonic devices has less variation in thickness.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-092138 filed Apr. 29, 2016, which is hereby incorporated by reference herein in its entirety.

What is claimed is:

1. An ultrasonic transducer manufacturing method for manufacturing an ultrasonic transducer including an ultrasonic device configured to perform at least one of transmission and reception of ultrasonic waves, the method comprising:
a first step of mounting the ultrasonic device on a substrate;
a second step of preparing a protective film having an acoustic matching layer thereon; and
a third step of placing the protective film having the acoustic matching layer thereon over the ultrasonic device such that the acoustic matching layer is in contact with the ultrasonic device.

2. The ultrasonic transducer manufacturing method according to claim 1, wherein in the third step, the protective film having the acoustic matching layer thereon is placed to cover the ultrasonic device and the substrate together.

3. The ultrasonic transducer manufacturing method according to claim 1, wherein the third step is done by vacuum lamination.

4. The ultrasonic transducer manufacturing method according to claim 1, further comprising a fourth step of mounting a circuit device on the substrate.

5. The ultrasonic transducer manufacturing method according to claim 4, wherein in the fourth step, the circuit device is positioned between the substrate and the ultrasonic device.

6. The ultrasonic transducer manufacturing method according to claim 5, wherein in the fourth step, the circuit device is mounted on one of two principal surfaces of the substrate, the one being a principal surface opposite a principal surface having the ultrasonic device thereon.

7. The ultrasonic transducer manufacturing method according to claim 1, wherein in the third step, the protective film having the acoustic matching layer thereon is placed by vacuum lamination on both two principal surfaces of the substrate.

8. The ultrasonic transducer manufacturing method according to claim 1, wherein the acoustic matching layer is made of silicone resin.

9. The ultrasonic transducer manufacturing method according to claim 1, wherein the substrate is a flexible circuit board.

10. The ultrasonic transducer manufacturing method according to claim 1, wherein the protective film is made of polyethylene terephthalate or polypropylene.

11. The ultrasonic transducer manufacturing method according to claim 1, wherein the protective film has a Young's modulus of 3 GPa to 30 GPa.

12. The ultrasonic transducer manufacturing method according to claim 1, wherein the protective film has a thickness of 5 μm to 40 μm.

13. The ultrasonic transducer manufacturing method according to claim 1, further comprising a fifth step of forming a light reflecting layer on the protective film.

14. The ultrasonic transducer manufacturing method according to claim 13, wherein the fifth step includes forming an adhesive layer on the protective film and forming the light reflecting layer on the adhesive layer.

15. The ultrasonic transducer manufacturing method according to claim 13, wherein the light reflecting layer is made of gold.

16. The ultrasonic transducer manufacturing method according to claim 14, wherein the adhesive layer is made of polydimethylsiloxane.

17. The ultrasonic transducer manufacturing method according to claim 1, wherein the first step includes mounting the ultrasonic device on a circuit board, and mounting the circuit board having the ultrasonic device thereon on a flexible circuit board which is the substrate.

18. An ultrasonic transducer comprising:
a substrate;
an ultrasonic device disposed on the substrate, the ultrasonic device being configured to perform at least one of transmission and reception of ultrasonic waves; and
a continuous protective film having an acoustic matching layer thereon, the protective film being disposed over the ultrasonic device and the substrate to cover the ultrasonic device and the substrate together such that the acoustic matching layer is in contact with the ultrasonic device.

19. The ultrasonic transducer according to claim 18, further comprising a circuit device disposed on the substrate.

20. The ultrasonic transducer according to claim 18, wherein the continuous protective film having the acoustic matching layer thereon is disposed on both two principal surfaces of the substrate.

21. The ultrasonic transducer according to claim 18, wherein the substrate is a flexible circuit board.

22. The ultrasonic transducer according to claim 18, further comprising a plurality of circuit boards,
wherein the ultrasonic device is disposed on each of the circuit boards, which are disposed on a flexible circuit board which is the substrate.
